(19) United States
(12) Patent Application Publication
(10) Pub. No.: US 2024/0314471 A1
(43) Pub. Date: Sep. 19, 2024

(54) ELECTRONIC DEVICE, MONITORING SYSTEM AND MONITORING METHOD

(71) Applicant: HIMAX TECHNOLOGIES LIMITED, Tainan City (TW)

(72) Inventors: Tsung-Yau Huang, Tainan City (TW); Wen-Jen Huang, Tainan City (TW)

(73) Assignee: HIMAX TECHNOLOGIES LIMITED, Tainan City (TW)

(21) Appl. No.: 18/183,958

(22) Filed: Mar. 15, 2023

(51) Int. Cl. H04Q 9/00

(52) U.S. Cl. CPC H04Q 9/00

(57) ABSTRACT

An electronic device, a monitoring system and a monitoring method are provided. The electronic device includes a sensor and a processor. The sensor is configured to sense a sensing object and output a sensing data. The processor is coupled to the sensor, and configured to receive the sensing data. The processor generates a plurality of superimposed data according to the sensing data and a plurality of noise data. The processor analyzes the sensing data and the plurality of superimposed data to generate a plurality of recognition results and a plurality of confidence levels. The processor outputs one of the plurality of recognition results to a cloud device, and further determine whether to output the sensing data to the cloud device according to the plurality of recognition results or the plurality of confidence levels.

### BACKGROUND

### Technical Field

The disclosure relates a monitoring technology, particularly, the disclosure relates to an electronic device, a monitoring system and a monitoring method.

### Description of Related Art

Because the traditional electric meter has to manually record the meter information recorded on the electric meter, the electric meter company needs to use more manpower and expense to record the meter information of a large number of electric meters. Although the electricity meter company may use some monitoring equipment to monitor the electric meter, the traditional monitoring equipment still has the problems of high energy consumption and low monitoring reliability.

### SUMMARY

The electronic device of the disclosure includes a sensor and a processor. The sensor is configured to sense a sensing object and output a sensing data. The processor is coupled to the sensor, and configured to receive the sensing data. The processor generates a plurality of superimposed data according to the sensing data and a plurality of noise data. The processor analyzes the sensing data and the plurality of superimposed data to generate a plurality of recognition results and a plurality of confidence levels. The processor outputs one of the plurality of recognition results to a cloud device, and further determine whether to output the sensing data to the cloud device according to the plurality of recognition results or the plurality of confidence levels.

The monitoring system of the disclosure includes a cloud device and an electronic device. The electronic device is coupled to the cloud device. The electronic device includes a sensor and a processor. The sensor is configured to sense a sensing object and output a sensing data. The processor is coupled to the sensor, and configured to receive the sensing data. The processor generates a plurality of superimposed data according to the sensing data and a plurality of noise data. The processor analyzes the sensing data and the plurality of superimposed data to generate a plurality of recognition results and a plurality of confidence levels. The processor outputs one of the plurality of recognition results to the cloud device, and further determine whether to output the sensing data to the cloud device according to the plurality of recognition results or the plurality of confidence levels. When the cloud device receives the sensing data, the cloud device analyzes the sensing data to generate another recognition result.

The monitoring method includes the following steps: sensing a sensing object and output a sensing data; generating a plurality of superimposed data according to the sensing data and a plurality of noise data; analyzing the sensing data and the plurality of superimposed data to generates a plurality of recognition results and a plurality of confidence levels; outputting one of the plurality of recognition results to a cloud device; and determining whether to output the sensing data to the cloud device according to the plurality of recognition results or the plurality of confidence levels.

Based on the above, according to the electronic device, the monitoring system and the monitoring method of the disclosure, the electronic device can effectively monitor the sensing object to generate the best recognition result.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic diagram of a monitoring system according to an embodiment of the disclosure.

FIG. 2 is a schematic diagram of data processing according to an embodiment of the disclosure.

FIG. 3 is a flow chart of a monitoring method according to an embodiment of the disclosure.

FIG. 4 is a schematic diagram of data processing according to an embodiment of the disclosure.

FIG. 5 is a schematic diagram of sensing data according to an embodiment of the disclosure.

FIG. 6 is a schematic diagram of a monitoring system according to an embodiment of the disclosure.

### DESCRIPTION OF THE EMBODIMENTS

Reference will now be made in detail to the exemplary embodiments of the disclosure, examples of which are illustrated in the accompanying drawings. Whenever possible, the same reference numbers are used in the drawings and the description to refer to the same or like components.

Certain terms are used throughout the specification and appended claims of the disclosure to refer to specific components. Those skilled in the art should understand that electronic device manufacturers may refer to the same components by different names. This article does not intend to distinguish those components with the same function but different names. In the following description and rights request, the words such as “comprise” and “include” are open-ended terms, and should be explained as “including but not limited to . . . ”

The term “coupling (or electrically connection)” used throughout the whole specification of the present application (including the appended claims) may refer to any direct or indirect connection means. For example, if the text describes that a first device is coupled (or connected) to a second device, it should be interpreted that the first device may be directly connected to the second device, or the first device may be indirectly connected through other devices or certain connection means to be connected to the second device.

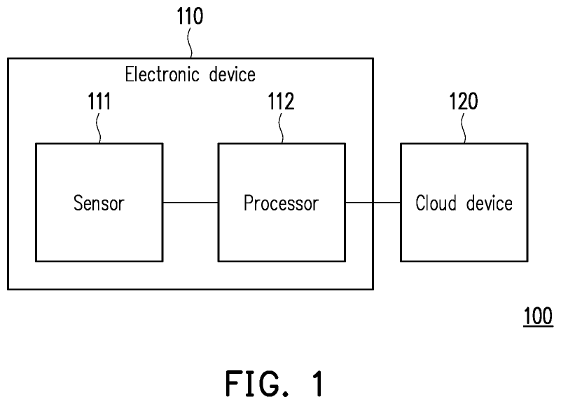

FIG. 1 is a schematic diagram of a monitoring system according to an embodiment of the disclosure. Referring to FIG. 1, the monitoring system 100 includes an electronic device 110 and a cloud device 120. The electronic device 110 includes a sensor 111 and a processor 112. The sensor 111 is coupled to processor 112, and the processor 112 is coupled to the cloud device 120 through a wired or wireless connection. The cloud device 120 may be a cloud server, and may be implemented as a cloud recognition system, but the disclosure is not limited thereto. The electronic device 110 may be an edge device or an internet of things (IoT) device, but the disclosure is also not limited thereto.

In the embodiment of the disclosure, the electronic device 110 may be used as a monitoring device, and configured to monitor a sensing object. The sensor 111 may be an image sensor, and the sensing data may be an image data. Specifically, the sensing object may be an electric meter, but the disclosure is not limited thereto. The electronic device 110 may obtain the image with a number information on the electric meter by the sensor 111. The processor 112 of the electronic device 110 may recognize the image with a number information to obtain a best recognition result of the number information, and transmit the best recognition result of the number information to the cloud device 120, so that the cloud device 120 may record information for subsequent use, such as cost calculation. Moreover, in the case of low recognition reliability, the processor 112 of the electronic device 110 may additionally transmit the image data to the cloud device 120, so that the cloud device 120 may perform image analysis with a greater amount of computation to generate another recognition result.

However, in one embodiment of the disclosure, the electronic device 110 may also be configured to monitor a doorbell or an intercom. The sensor 111 may be an audio sensor, and the sensing data is an audio data. Specifically the electronic device 110 may obtain the audio data by the sensor 111. The processor 112 of the electronic device 110 may recognize the audio data to obtain a best recognition result of an audio content, and transmit the best recognition result of the audio content to the cloud device 120, so that the cloud device 120 may perform related operations according to the sound content. Moreover, in the case of low recognition reliability, the processor 112 of the electronic device 110 may further transmit the audio data to the cloud device 120, so that the cloud device 120 may perform audio analysis with a greater amount of computation.

In the embodiment of the disclosure, the processor 112 may include, for example, a central processing unit (CPU), a graphic processing unit (GPU), or other programmable general-purpose or special-purpose microprocessor, digital signal processor (DSP), application specific integrated circuit (ASIC), programmable logic device (PLD), other similar processing circuits or a combination of these devices. In the embodiment of the disclosure, the electronic device 110 may further include a storage unit, such as a memory. The processor 112 may be coupled to the storage unit. The storage unit may be, for example, a non-volatile memory (NVM). The storage unit may store relevant programs, modules, data or algorithms for realizing various embodiments of the disclosure, for the processor 1112 to access and execute to realize the relevant functions and operations described in the various embodiments of the disclosure.

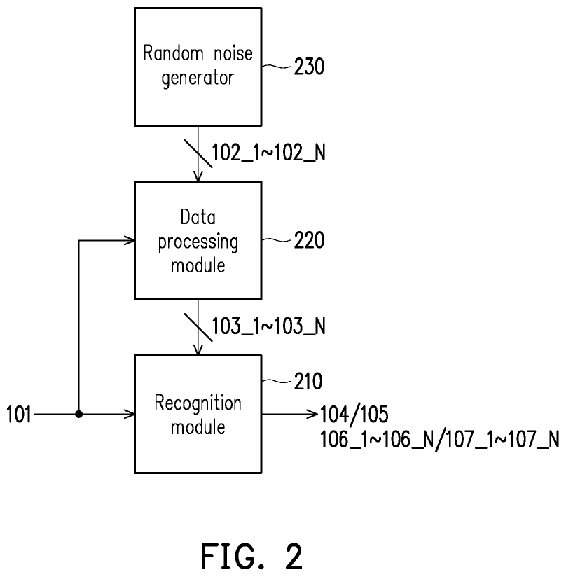

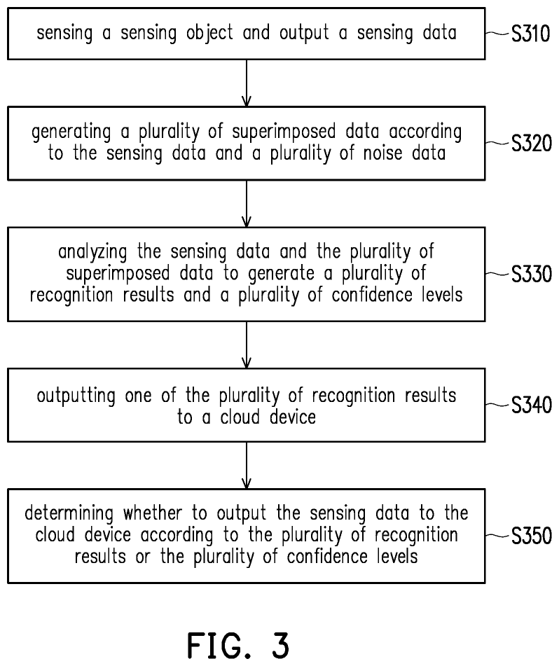

FIG. 2 is a schematic diagram of data processing according to an embodiment of the disclosure. FIG. 3 is a flow chart of a monitoring method according to an embodiment of the disclosure. Referring to FIG. 1 to FIG. 3, the processor 112 may execute a recognition module 210, a data processing module 220 and a random noise generator 230, and perform the following steps S310 to S350. In step S310, the sensor 111 may sense a sensing object and output a sensing data 101. In step S320, the data processing module 220 may generate a plurality of superimposed data 103_1˜103_N according to the sensing data 101 and a plurality of noise data 102_1˜102_N, where N is a positive integer. The processor 112 may execute the random noise generator 230 to generate the plurality of noise data 102_1˜102_N. The plurality of noise data 102_1˜102_N are different data. The processor 112 may execute the processing module 220 to respectively superimpose the plurality of noise data 102_1˜102_N and the sensing data 101 to generate the plurality of superimposed data 103_1˜103_N.

In step S330, the recognition module 210 may analyze the sensing data 101 and the plurality of superimposed data 103_1˜103_N to generate a plurality of recognition results 104, 106_1˜106_N and a plurality of confidence levels 105, 107_1˜107_N. In step S340, the recognition module 210 may output one of the plurality of recognition results 104, 106_1˜106_N to the cloud device 120. In step S350, the processor 112 may determine whether to output the sensing data 101 to the cloud device 120 according to the plurality of recognition results 104, 106_1˜106_N or the plurality of confidence levels 105, 107_1˜107_N.

Specifically, in the embodiment of disclosure, the recognition module 210 may include a convolutional neural network model (CNN). The convolutional neural network model (CNN) may be pre-trained to be able to recognize, for example, the image data or audio data. The recognition module 210 may input the sensing data 101 to the convolutional neural network model, so that the convolutional neural network model may output the corresponding recognition result 104 and the confidence level 105. Moreover, the recognition module 210 may respectively input the plurality of superimposed data 103_1˜103_N to the convolutional neural network model, so that the convolutional neural network model may output the corresponding recognition result 106_1˜106_N and the confidence level 107_1˜107_N. In the embodiment of disclosure, the processor 112 may output a most consistent recognition result among the plurality of recognition results whose confidence level is higher than or equal to a threshold level to the cloud device 120. Moreover, the processor 112 may further determine whether the plurality of confidence levels 105, 107_1˜107_N are lower than the threshold level. When the processor 112 determines that at least one of the confidence levels 105, 107_1˜107_N is lower than the threshold level, the processor 112 may also output the sensing data 101 to the cloud device 120 (regardless of whether the recognition results are consistent). Even, when the processor 112 determines the plurality of recognition results 104, 106_1˜106_N are inconsistent, the processor 112 may also output the sensing data 101 to the cloud device 120 (regardless of the confidence level).

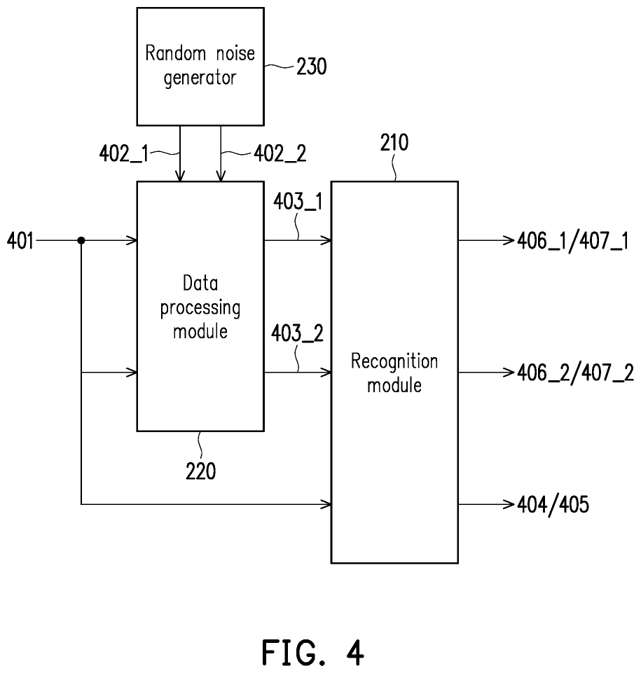

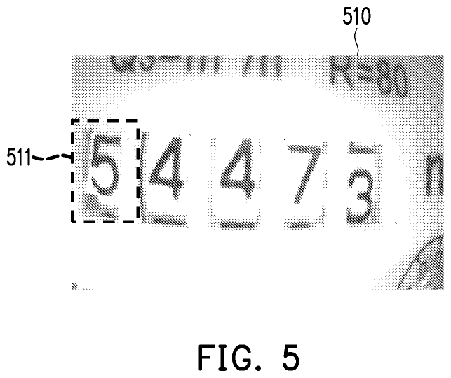

FIG. 4 is a schematic diagram of data processing according to an embodiment of the disclosure. FIG. 5 is a schematic diagram of sensing data according to an embodiment of the disclosure. Referring FIG. 1, FIG. 4 and FIG. 5, the following description takes the electronic device 110 used for monitoring an electric meter as an example. The sensor 111 may be configured to sense the electric meter to obtain an image data 401 of an image 510 of FIG. 5, and the processor 112 may be configured to recognize, for example, a number image on the image 510 of FIG. 5 to obtain the number information. In the embodiment of the disclosure, due to there may be dirt on the meter or sensor or the image sensing environment is not good, so in order to ensure the correctness of image recognition, the processor 112 may additionally generate multiple recognition samples for multiple recognition tests. The processor 112 may determine to output the best recognition result to the cloud device 120 through the consistency of the recognition results and the confidence levels, and determine whether to further output the image data 401 to the cloud device 120 for subsequent more accurate recognition.

Specifically, the processor 111 may execute the random noise generator 230 to generate two noise image data 402_1, 402_2 for the data processing module 220. The noise image data 402_1, 402_2 may respectively correspond to a random image, and the pixel value of each pixel of the random image may random select one value from −1, 0 and 1. The processor 112 may execute the data processing module 220 to respectively superimpose the noise image data 402_1, 402_2 and the image data 401 to generate two superimposed image data 403_1, 403_2 as the additional recognition samples for the recognition module 210. Then, the processor 112 may execute the recognition module 210 to analyze the image data 401 and the superimposed image data 403_1, 403_2. The recognition module 210 may generate the recognition result 404 and the confidence level 404 according to the image data 401. The recognition module 210 may generate the recognition result 406_1 and the confidence level 407_1 according to the superimposed image data 403_1. The recognition module 210 may generate the recognition result 406_2 and the confidence level 407_2 according to the superimposed image data 403_2.

For example, the recognition result 404 may be number information “5”, and the confidence level 405 may be 95%. The recognition result 406_1 may be number information “5”, and the confidence level 407_1 may be 93%. The recognition result 406_2 may be number information “5”, and the confidence level 407_2 may be 92%. The threshold level may be pre-set to 90%. Thus, due to the recognition results 404, 406_1, 406_2 are consistent, and the confidence levels 405, 407_1, 407_2 are higher than or equal to the threshold level 90%, the processor 112 may determine that the most consistent recognition result is number information “5” and only output the number information “5” of the most consistent recognition result to the cloud device 120.

As another example, the recognition result 404 may be number information “5”, and the confidence level 405 may be 95%. The recognition result 406_1 may be number information “5”, and the confidence level 407_1 may be 92%. The recognition result 406_2 may be number information “4”, and the confidence level 407_2 may be 90%. Thus, although the confidence levels 405, 407_1, 407_2 are higher than or equal to the threshold level 90%, but the recognition results 404, 406_1, 406_2 are inconsistent, so the processor 112 may output the number information “5” of the most consistent recognition result (or if the recognition result 404, 406_1, 406_2 are all different, one of the recognition results is randomly selected), and further output the image data 401 (i.e. the original image) to the cloud device 120 for subsequent more accurate recognition.

As another example, the recognition result 404 may be number information “5”, and the confidence level 405 may be 95%. The recognition result 406_1 may be number information “5”, and the confidence level 407_1 may be 87%. The recognition result 406_2 may be number information “5”, and the confidence level 407_2 may be 90%. Thus, although the recognition results 404, 406_1, 406_2 are consistent, but the confidence level 407_1 is lower than the threshold level 90%, so the processor 112 may determine that the most consistent recognition result is number information “5” and output the number information “5” of the most consistent recognition result to the cloud device 120, and further output the image data 401 (i.e. the original image) to the cloud device 120 for subsequent more accurate recognition.

Therefore, the electronic device 110 may realize an effective image recognition function, and can periodically sense the electric meter to effectively monitor the electric meter. Moreover, due to the electronic device 110 further provides image data 401 with larger data to the cloud device 120 only when the recognition reliability is insufficient (i.e. the recognition result is inconsistent and/or the confidence level is too low), the amount of communication between the electronic device and the cloud device may be effectively saved, and energy consumption caused by communication may be also saved.

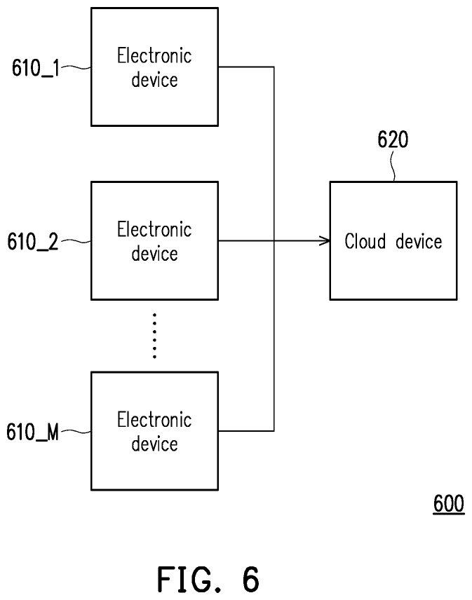

FIG. 6 is a schematic diagram of a monitoring system according to an embodiment of the disclosure. Referring to FIG. 6, the monitoring system 600 includes a plurality of electronic devices 610_1˜610_M and a cloud device 620, where M is a positive integer. The plurality of electronic devices 610_1˜610_M are respectively coupled to the cloud device 620 through a wired or wireless connection. The plurality of electronic devices 610_1˜610_M and the cloud device 620 may realize the electronic device 110 and the cloud device 120 of above-mentioned embodiments, so detailed technical features and performance can refer to the description of the above-mentioned embodiments, and will not be repeated here.

In the embodiment of the disclosure, the monitoring system 600 may be a smart meter system, and the plurality of electronic devices 610_1˜610_M may be configured to sense and monitor a plurality of electric meters. The plurality of electronic devices 610_1˜610_M may automatically and periodically obtain image data of the plurality of electric meters, and automatically recognize the image data of the plurality of electric meters to obtain and report the best recognition results of the number information of the plurality of electric meters to cloud device 620. Moreover, if the recognition results of the number information of any one of the plurality of electric meters are inconsistent and/or the confidence level is too low, the corresponding electronic device may further provide the original image data to the cloud device 620 for subsequent more accurate recognition.

In summary, the electronic device, the monitoring system and the monitoring method of the disclosure may effectively monitor the sensing object to generate the recognition result, and provide the recognition result to the cloud device. Moreover, only when the recognition reliability of the recognition result is insufficient, the electronic device may further provide the original sensing data to the cloud device for subsequent more accurate recognition. Therefore, the amount of communication between the electronic device and the cloud device may be effectively saved, and energy consumption caused by communication may be also saved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An electronic device, comprising:
a sensor, configured to sense a sensing object and output a sensing data; and
a processor, coupled to the sensor, and configured to receive the sensing data,
wherein the processor generates a plurality of superimposed data according to the sensing data and a plurality of noise data, and the processor analyzes the sensing data and the plurality of superimposed data to generate a plurality of recognition results and a plurality of confidence levels,
wherein the processor outputs one of the plurality of recognition results to a cloud device, and further determine whether to output the sensing data to the cloud device according to the plurality of recognition results or the plurality of confidence levels.

2. The electronic device according to claim 1, wherein the processor executes a random noise generator to generate the plurality of noise data, and the processor respectively superimposes the plurality of noise data and the sensing data to generate the plurality of superimposed data.

3. The electronic device according to claim 1, wherein the processor executes a recognition module to analyze the sensing data and the plurality of superimposed data to generate the plurality of recognition results and the plurality of confidence levels, and the processor outputs a most consistent recognition result among the plurality of recognition results whose confidence level is higher than or equal to the threshold level to the cloud device.

4. The electronic device according to claim 1, wherein the recognition module comprises a convolutional neural network model.

5. The electronic device according to claim 1, wherein the processor determines whether the plurality of confidence levels are lower than a threshold level, when the processor determines that at least one of the confidence levels is lower than the threshold level, the processor outputs the sensing data to the cloud device.

6. The electronic device according to claim 1, wherein the processor determines whether the plurality of recognition results are consistent, when the processor determines the plurality of recognition results are inconsistent, the processor outputs the sensing data to the cloud device.

7. The electronic device according to claim 1, wherein the sensor is an image sensor, and the sensing data is an image data.

8. The electronic device according to claim 1, wherein the sensing object is an electric meter, and the plurality of recognition results are a plurality of number information.

9. The electronic device according to claim 1, wherein the sensor is an audio sensor, and the sensing data is an audio data.

10. The electronic device according to claim 1, wherein when the cloud device receives the sensing data, the cloud device analyzes the sensing data to generate another recognition result.

11. A monitoring system, comprising:
a cloud device; and
an electronic device, coupled to the cloud device, and comprising:
a sensor, configured to sense a sensing object and output a sensing data; and
a processor, coupled to the sensor, and configured to receive the sensing data,
wherein the processor generates a plurality of superimposed data according to the sensing data and a plurality of noise data, and the processor analyzes the sensing data and the plurality of superimposed data to generate a plurality of recognition results and a plurality of confidence levels,
wherein the processor outputs one of the plurality of recognition results to the cloud device, and further determine whether to output the sensing data to the cloud device according to the plurality of recognition results or the plurality of confidence levels,
wherein when the cloud device receives the sensing data, the cloud device analyzes the sensing data to generate another recognition result.

12. The monitoring system according to claim 11, wherein the processor executes a random noise generator to generate the plurality of noise data, and the processor respectively superimposes the plurality of noise data and the sensing data to generate the plurality of superimposed data.

13. The monitoring system according to claim 11, wherein the processor executes a recognition module to analyze the sensing data and the plurality of superimposed data to generate the plurality of recognition results and the plurality of confidence levels, and the processor outputs a most consistent recognition result among the plurality of recognition results whose confidence level is higher than or equal to the threshold level to the cloud device.

14. The monitoring system according to claim 11, wherein the recognition module comprises a convolutional neural network model.

15. The monitoring system according to claim 11, wherein the processor determines whether the plurality of confidence levels are lower than a threshold level, when the processor determines that at least one of the confidence levels is lower than the threshold level, the processor outputs the sensing data to the cloud device.

16. The monitoring system according to claim 11, wherein the processor determines whether the plurality of recognition results are consistent, when t the processor determines the plurality of recognition results are inconsistent, the processor outputs the sensing data to the cloud device.

17. The monitoring system according to claim 11, wherein the sensor is an image sensor, and the sensing data is an image data.

18. The monitoring system according to claim 11, wherein the sensing object is an electric meter, and the plurality of recognition results are a plurality of number information.

19. The monitoring system according to claim 11, wherein the sensor is an audio sensor, and the sensing data is an audio data.

20. A monitoring method, comprising:
sensing a sensing object and output a sensing data;
generating a plurality of superimposed data according to the sensing data and a plurality of noise data;
analyzing the sensing data and the plurality of superimposed data to generates a plurality of recognition results and a plurality of confidence levels;
outputting one of the plurality of recognition results to a cloud device; and
determining whether to output the sensing data to the cloud device according to the plurality of recognition results or the plurality of confidence levels.
